(19) United States
(12) Patent Application Publication
(10) Pub. No.: US 2026/0076218 A1
(43) Pub. Date: Mar. 12, 2026

(54) SUBSTRATE ATTACH PADS AND RELATED METHODS

(71) Applicant: SEMICONDUCTOR COMPONENTS INDUSTRIES, LLC, Scottsdale, AZ (US)

(72) Inventors: Lijuan WANG, Suzhou (CN); Ian Ceazar Bucayon BARIAS, Butuan City (PH); JingJing ZUO, Suzhou (CN); XinYue MAO, Suzhou (CN)

(73) Assignee: SEMICONDUCTOR COMPONENTS INDUSTRIES, LLC, Scottsdale, AZ (US)

(21) Appl. No.: 18/830,267

(22) Filed: Sep. 10, 2024

(51) Int. Cl. H01L 23/495

(52) U.S. Cl. CPC H10W 70/465

(57) ABSTRACT

Implementations of a leadframe may include a substrate attach portion including a first largest planar surface and a second largest planar surface on a side opposing the first largest planar surface; and a substrate opening formed in a material of the first largest planar surface of the substrate attach portion. The substrate opening may be configured to receive a perimeter of a substrate therein.

### BACKGROUND

### 1. Technical Field

Aspects of this document relate generally to semiconductor packages, such as packages for semiconductor die. More specific implementations involve leadframe packages.

### 2. Background

Various designs have been devised for semiconductor packages that work to provide electronic connections between a semiconductor die included in the semiconductor package and a circuit or motherboard to which the semiconductor package is attached. Other designs work to protect a semiconductor die from humidity. Yet other designs assist with providing shock and vibration protection for a semiconductor die during operation of the semiconductor package.

### SUMMARY

Implementations of a leadframe may include a substrate attach portion including a first largest planar surface and a second largest planar surface on a side opposing the first largest planar surface; and a substrate opening formed in a material of the first largest planar surface of the substrate attach portion. The substrate opening may be configured to receive a perimeter of a substrate therein.

Implementations of a leadframe may include one, all, or any of the following:

The substrate attach portion may be one of a plurality of substrate attach portions where each of the plurality of substrate attach portions may include a substrate opening.

The leadframe may include one or more leads fixedly coupled to the substrate attach portion.

The leadframe may include one or more leads fixedly coupled to the substrate attach portion through one or more tie bars.

The substrate attach portion may form an electrical connection with the substrate through the substrate opening.

The perimeter of the substrate opening may be larger than a perimeter of the substrate.

The substrate may include one or more semiconductor die thereon.

The substrate may be a direct bonded copper substrate.

Implementations of a semiconductor package may include a substrate attach portion; and a substrate recess formed into a material of the substrate attach portion. The substrate recess may be configured to receive an entire perimeter of a substrate therein. A substrate including at least one semiconductor die coupled thereto may be included where the substate is coupled into the substrate recess.

Implementations of a semiconductor package may include one, all, or any of the following:

The substrate attach portion may be one of a plurality of substrate attach portions where each of the plurality of substrate attach portions may include a substrate recess.

The leadframe may include one or more leads fixedly coupled to the substrate attach portion.

The leadframe may include one or more leads fixedly coupled to the substrate attach portion through one or more tie bars.

The substrate attach portion forms an electrical connection with the substrate through the substrate recess.

The perimeter of the substrate recess may be larger than a perimeter of the substrate.

The substrate may include two or more semiconductor die thereon.

The substrate may be a direct bonded copper substrate.

Implementations of a method of forming a substrate may include providing a substrate attach portion with a largest planar surface; and one of stamping, punching, drilling, etching, or cutting a substrate recess into a material of the largest planar surface of the substrate attach portion. The substrate recess may be configured to receive an entire perimeter of a substrate therein.

Implementations of a method of forming a leadframe may include one, all, or any of the following:

The method may include dispensing a substrate attach material into the substrate recess.

The method may include placing a substrate into the substrate recess onto the substrate attach portion. The method may include one of curing, sintering, or reflowing the substrate attach material to the substrate.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a detail perspective view of a substrate/leadframe and a perspective view of a panel/set/array of leadframes during a manufacturing process;

FIG. 2 is a detail perspective view of a die attach pad/substrate attach portion that includes a substrate opening therein;

FIG. 3 is a detail perspective view of a die attach pad with a substrate coupled into a substrate opening;

FIG. 4 is a diagram of the dimensions of a substrate opening of a die attach pad;

FIG. 5 is a perspective view of an implementation of a multi-chip module at three points in a method of making the same;

FIG. 6 is a top view of an implementation of a multi-chip module;

FIG. 7 is a detail view of the die attach pad of FIG. 3;

FIG. 8 is a side cross sectional view of an implementation of two overlapping semiconductor die coupled to a substrate;

FIG. 9 is a side cross sectional view of an implementation of two overlapping semiconductor die coupled to a substrate;

FIG. 10 is a side cross sectional view of an implementation of a two overlapping semiconductor die coupled to a substrate; and

FIG. 11 is a side cross sectional view of an implementation of two stacked semiconductor die coupled to a substrate.

### DESCRIPTION

This disclosure, its aspects and implementations, are not limited to the specific components, assembly procedures or method elements disclosed herein. Many additional components, assembly procedures and/or method elements known in the art consistent with the intended substrate attach pads will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such substrate attach pads, and implementing components and methods, consistent with the intended operation and methods.

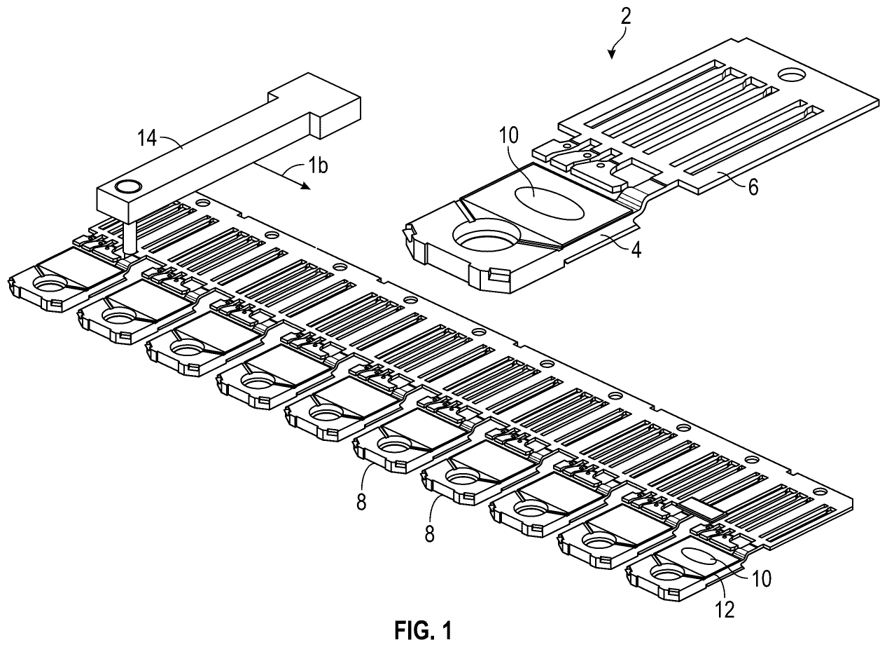

Referring to FIG. 1, an implementation of a substrate/leadframe 2 is illustrated that includes a die attach pad 4 and plurality of leads 6 coupled to the die attach pad 4. While leadframe substrates are illustrated in the examples in this document, various other substrate types could be used that implement the principles disclosed in this document, such as, by non-limiting example, direct bonded copper substrates, integrated metal substrates, laminated substrates, or printed circuit boards. As illustrated in FIG. 1, during manufacturing, the leadframe 2 may be one unit of a set/frame/panel of leadframes 8 which are being processed together in a semiconductor packaging process. At a certain point in the process, the various leadframes 8 will be singulated one from each other into individual semiconductor packages. In various semiconductor package implementations, one or more semiconductor die are attached to the die attach portion. In some method implementations, a semiconductor die is directly attached to the die attach pad. In other method implementations, like those discussed in this document, a substrate is attached to the die attach pad (leading to the alternate term “substrate attach portion” used herein). The substrate that is attached may be any type of substrate disclosed in this document. Eventually in the manufacturing process, a semiconductor die (or multiple die) will be attached directly to the substrate attached to the die attach pad/substrate attach portion. In some implementations, when the substrate is attached to the die attach pad/substrate attach portion, a semiconductor die (or multiple die) is already attached to the substrate.

In the implementation of FIG. 1, the panel of leadframes 8 is illustrated at a point where a substrate attach material 10 has been applied to the die attach portions 12 in preparation for placement of substrates on the substrate attach material 10. Following placement of the substrates, one or more semiconductor die will then be placed on the substrates. As illustrated in FIG. 1, during the semiconductor die placement/attach process, hook 14 engages with the panel of leadframes 8 and shifts/moves it in the direction of arrow 16. Because at this stage the substrate attach material is not fully cured/sintered/reflowed, particularly where a soft solder material is used as the substrate attach material, the movement of the panel of leadframes 8 in the direction of the arrow (X direction) causes a shift in the position of the placed substrates in a direction opposite the arrow, resulting in observed translation, rotation, and skewing of the placement of the substrates from their original location. The observed effect does not result in a statistically significant overall average movement of the substrates in the opposite X direction of the arrow 16, but rather a statistically significant increased variation in the observed standard deviation of the placement in the X direction. This indicates that, while all substrates experience some effect, they experience it differently from the others and the most commonly observed effect is a rotation/skewing of the substrate position from the original placement location.

In testing where polyimide tape rather than a soft solder was used to attach the substrate to the die attach pads, no statistically significant effect in standard deviation was observed—indicating that it is physical movement of the substrates when placed on a soft solder in response to the movement of the panel of leadframes that is causing the observed increase in standard deviation. The problem with rotation and skewing of the substrate is that when the semiconductor die(s) are attached to the substrate, the subsequent wirebonding process can result in incorrectly placed leads due to the rotation of the substrate. The incorrectly placed leads result in yield loss or potential reliability problems if a wirebond is marginally, but not fully attached.

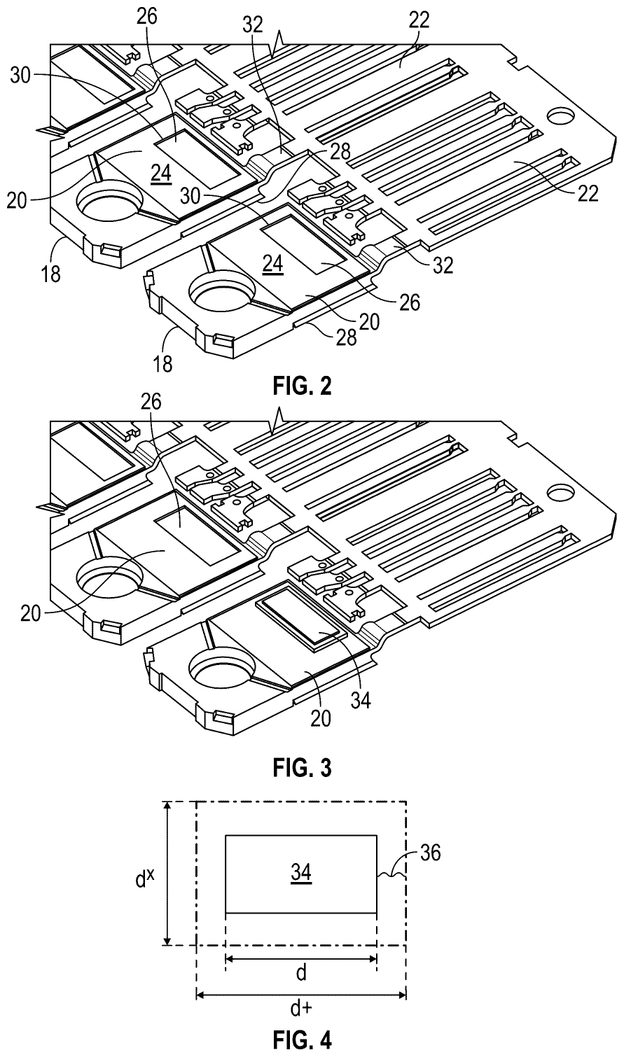

Referring to FIG. 2, a detail view of a panel of leadframes 18 is illustrated that shows a closeup view of the die attach pads/substrate attach portions 20. Like the leadframes illustrated in FIG. 1, a plurality of leads 22 are each attached to the die attach pads 20 through a tie bar 32. In other implementations, however, the plurality of leads 22 (or one, all, or some of the plurality of leads) may be directly coupled to the die attach pads/substrate attach portions 20. Formed in a first largest planar surface 24 in the material of each of the die attach pads 20 is a substrate opening 26. As illustrated, each substrate attach portion 20 also includes a second largest planar surface 28 that is on an opposing side from the first largest planar surface 24. As illustrated, the substrate opening 26 includes a perimeter 30 that forms a closed shape, in this case, a rectangular shape. While a rectangular shape is illustrated in the figures in this document, the shape of the perimeter 30 of the substrate opening 26 may be any of a wide variety of shapes, including, by non-limiting example, square shapes, circular shapes, elliptical shapes, triangular shapes, polygonal shapes, or any closed shape that corresponds with the particular shape of a substrate.

As illustrated in FIG. 2, the substrate opening 26 extends into the material of the substrate attach portion 20. During a method of manufacturing the leadframes, initially, the substrate attach portion 20 is created by punching, stamping, or cutting a sheet of material to form the outline of the substrate attach portion 20 with a substantially flat first and second largest planar surfaces 24, 28, respectively. In this substantially flat first largest planar surface, the substrate opening 26 is formed into the material of the substrate. Various processes for forming the substrate opening 26 that may be used in various methods of manufacturing a leadframe may include, by non-limiting example, stamping, punching, drilling, etching, or cutting, or another process capable of spreading/removing the material of the substrate attach portion 20. In a particular implementation, computer numerical control (CNC) milling/drilling may be used to form the substrate opening 26 into the material of the substrate attach portion 20 on the first largest planar surface 24.

Referring to FIG. 3, the panel of leadframes 18 is illustrated following dispensing/application of a substrate attach material (not shown in FIG. 3) into the substrate openings 26 and placing of a substrate 34 into the substrate openings 26 onto the substrate attach material. The substrate attach material may be any disclosed in this document including a soft solder material. Following placement of the substrate 34 into the substrate opening 26 of the substrate attach portion 20, various processes consistent with the material of the substrate attach material and the material(s) of the substrate itself are used to form a fixed bond between the substrate 34 and the substrate attach portion 20. For example, where a soft solder is used, a reflowing process may be employed to ensure complete wetting of the substrate 34 with the material of the substrate opening 26 and the formation of the desired metallic and intermetallic compounds that create the bond. This reflow process may also create an electrical connection with a side of the substrate 34 and the substrate opening 26 that has a desired electrical performance characteristic. In other method implementations, where the substrate attach material is not used to form an electrical connection with the substrate but is just used to form a fixed bond, like an epoxy or die attach material/film, a curing process may be used to form the bond. In some implementations, where the substrate attach material is used to form a metallic bond between the material of the substrate 34 and the material of the substrate opening 26, a sintering process may be used. In all of these processes, the shape of the substrate openings 26 works to prevent rotation/skew/displacement of the substrate until the bonding process is completed.

In testing, the effect of the use of the substrate opening 26 allowed for a reduction in observed standard deviation of the final position of the substrate following a reflow operation involving a die attach material that was a soft solder. Referring to FIG. 4, where the space on all sides of the substrate 34 was set to 0.2 mm through making the perimeter of the substrate opening 26 0.4 mm larger on each side (d+), shifting of the position of the substrate was controlled within a target value and a statistically significant reduction in placement standard deviation was observed versus when a substrate opening was not used. This reduction in placement in standard deviation translates into improved wirebonding and semiconductor die bonding behavior because the substrate remains located closer to its design position. While the use of a 0.2 mm spacing 36 is illustrated in FIG. 4, a smaller or larger one could be employed in various leadframe implementations to achieve a desired degree of reduction of substrate placement deviation.

A wide variety of substrate implementations could be utilized with the various substrate opening implementations disclosed herein. For example, the substrate may be a direct bonded copper (DBC) substrate that may contain traces and other structures formed thereon. Following bonding of the DBC substrate, one or more semiconductor die and/or one or more other passive components may be bonded/attached to the DBC substrate as part of a semiconductor package manufacturing operation. Other substrate types that could be utilized may include, by non-limiting example, ceramic substrates, insulated metal substrates, organic substrates, laminated substrates, or any other substrate type used in a semiconductor package.

As the substrate either contains one or more semiconductor die bonded thereto prior to bonding of the substrate into the substrate opening or one or more semiconductor die will be bonded thereto after the substrate bonding, a wide variety of semiconductor die may be utilized in semiconductor packages that utilize substrate openings. By non-limiting example, the semiconductor die could be a metal oxide field effect transistor (MOSFET), an insulated gate bipolar transistor (IGBT), a transistor, a diode, a power semiconductor die, a controller, a microcontroller, an field programmable gate array, a high-electron-mobility transistor, a random access memory (RAM), a flash memory, an electronically erasable programmable read-only memory (EEPROM), a microprocessor, or any of a wide variety of other semiconductor die. Various other passive components, such as, by non-limiting example, capacitors, resistors, sensors, inductors or other passive component types may be included as well in various semiconductor package implementations.

Various semiconductor die types that are formed using various semiconductor substrate material types could be utilized in various implementations. By non-limiting example, the semiconductor substrate types may be silicon, silicon carbide, silicon on insulator, gallium arsenide, ruby, sapphire, glass, or any other semiconductor material type.

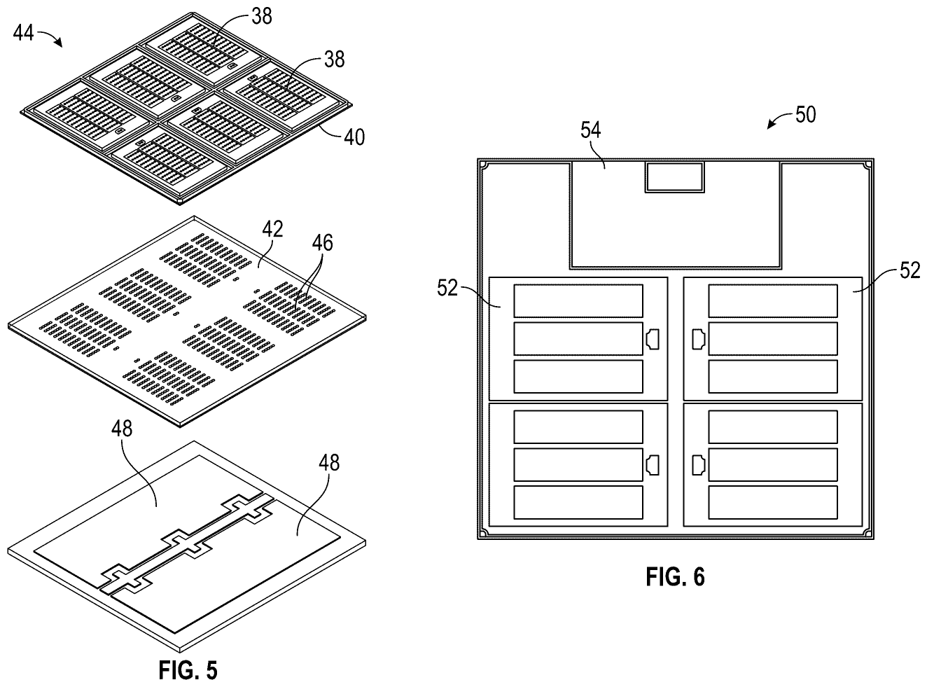

Examples of various substrate types and semiconductor die types that could be utilized in various semiconductor package implementations constructed using the principles disclosed in are illustrated in FIGS. 5-11. Referring to FIG. 5, an implementation of a multi-chip module 44 that includes six silicon carbide die 38 coupled onto an interposer 40 is illustrated. FIG. 5 also illustrates the silicon carbide die 38 following application of an electrically insulative material 42 (in this case, a mold compound) over the silicon carbide die 48 leaving a plurality of contacts 46 exposed therethrough. FIG. 5 also illustrates the multi-chip module following formation of contact pads 48 over the plurality of contacts 46. At this point, the multi-chip module 44 is ready for either insertion into a substrate opening on a substrate attach portion or for coupling to another substrate that will ultimately be inserted into the substrate opening. The use of the multi-chip module allows for semiconductor package designs that are more configurable the function of the package can be changed simply by changing the particular multi-chip module(s) included in the package design. FIG. 6 also illustrates another multichip module 50 that includes four semiconductor die 52 coupled to a interposer on which various pads 54 have been formed for source, drain, and gate connections.

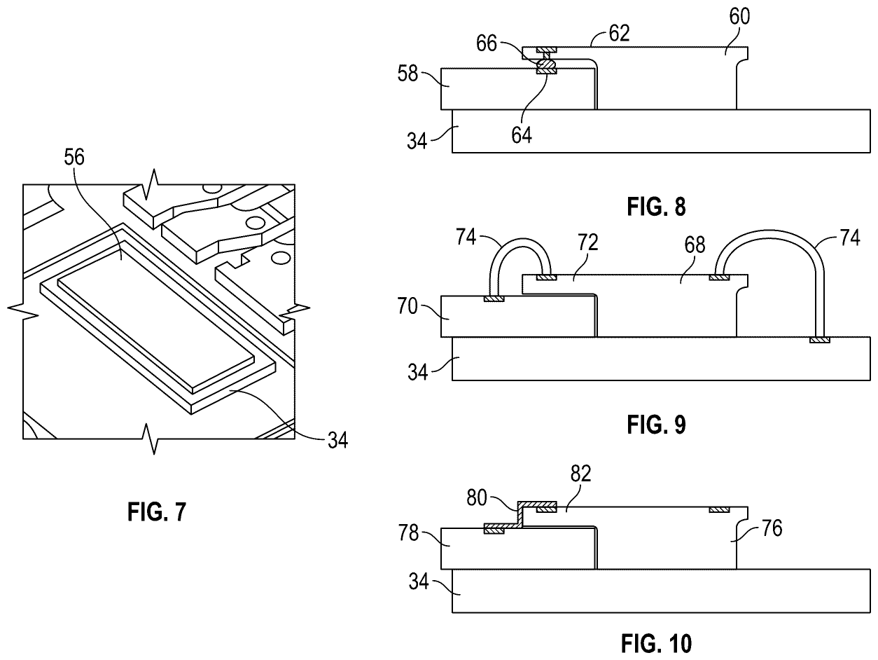

A wide variety of semiconductor die and semiconductor die configurations may be employed in various semiconductor package implementations. Referring to FIG. 7, a close up of the substrate 34 of FIG. 3 illustrated which shows a semiconductor die 56 coupled thereto. However, more than one semiconductor die may be included in a variety of configurations. For example, as illustrated in FIG. 8, two semiconductor die 58, 60 could be coupled to the substrate 34 which are in a stacked and partially overlapping configuration.

Here semiconductor die 60 includes an overhanging portion 62 that is electrically and mechanically coupled with a pad 64 using a solder bond 66. In this implementation, the use of the overhanging portion 62 serves to align the semiconductor 60 with the semiconductor die 58 and with its location on the substrate.

FIG. 9 illustrates another semiconductor die configuration that includes a semiconductor die 68 coupled over another semiconductor die 70 using overhanging portion 72. In this implementation, wirebonds 74 are used to form electrical connections between the semiconductor die 68, 70 and between the semiconductor die 68 and the substrate 34. FIG. 10 also illustrates another overlapping configuration where semiconductor die 76 is mechanically and electrically coupled to semiconductor die 78 through trace 80 which has been deposited over overhanging portion 82. Additional semiconductor die configurations are possible. For example, the semiconductor die may be placed on the substrate in an interlocking fashion where the perimeter of one semiconductor die serves to align the perimeter of one or more other semiconductor die.

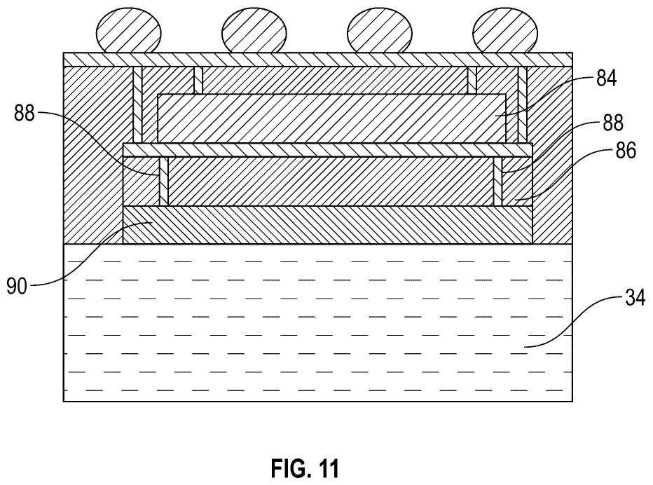

Yet other semiconductor die configurations are possible. Referring to FIG. 11, stacked die where the perimeter of a first semiconductor die 84 is contained fully or partially within the perimeter of a second semiconductor die 86 could be attached the substrate 34. In this implementations, through silicon or through oxide vias 88 are employed to allow the first semiconductor die 84 to electrically couple with the substrate 34 and/or the second semiconductor die 86 through interposer 90. In this implementation, the use of an additional redistribution layer 92 that includes balls 94 is illustrated indicating that additional components/circuit boards can be coupled/mounted above the substrate 34.

These non-limiting examples illustrate that a wide variety of semiconductor die types, substrate types, semiconductor die configurations, and substrate configurations can be used with the substrate openings disclosed herein.

In this document, the use of a substrate opening on a die attach pad/substrate attach portion included on a leadframe has been illustrated. However, the structure of a substrate opening could be utilized with different structures used in semiconductor packages to allow for bonding of a substrate to electrical routing/mechanical support and other substrate types. For example, a substrate opening could be included in a direct bonded substrate to allow for bonding of another substrate to the direct bonded substrate at the substrate opening. A substrate opening could be included in an FR4 or other organic substrate type to allow for placement/bonding of another substrate at that location. A substrate opening could be included in an insulated metal substrate to allow for a substrate to be placed/bonded to the insulated metal substrate at that location. In all of these combinations of substrates/packaging systems enabled by the use of the substrate opening, the substrate being bonded to the other substrate may be the same type of substrate or a different type of substrate in various semiconductor package implementations.

In semiconductor packages that employ substrate openings to allow for bonding of a substrate to a leadframe or other substrate, a wide variety of package designs can be employed. These may include, by non-limiting example, leaded semiconductor packages, leadless semiconductor packages, ball grid array (BGA) semiconductor packages, land grid array (LGA) semiconductor packages, pin grid array (PGA) semiconductor packages, multichip module semiconductor packages, power semiconductor packages, quad flat no-leads packages (QFN), thin small outline packages (TSOP), surface mount packages, small outline transistor packages, or any other semiconductor package type that employs a substrate.

For those semiconductor packages that employ leadframes to form all or a part of the structure of the semiconductor packages, a wide variety of materials may be employed. The material of the die attach pads and leads may be the same material formed from, by non-limiting example, copper, a copper alloy, an iron-nickel alloy, aluminum, an aluminum alloy, or any other metal material. Various other metals may be included in the structure of the leadframe as aids in forming metal-metal bonds with a circuit board/motherboard to which the leads of the leadframe will be attached or as aids in forming metal-metal bonds with components included in the semiconductor package. For example, the first largest planar surface, the second largest planar surface, or both the first largest planar surface and second largest planar surface of the die attach pad may be plated with another metal material that will aid in a soldering operation or other bonding operation either with the substrate or with circuit/motherboard. Where the first largest planar surface is plated with a material that aids in the soldering operation, the plating of the plated metal may take place after formation of the substrate openings in various method implementations. In other implementations, plating of the leads may be carried out either to improve subsequent bonding of the leads to a circuit/motherboard and/or to aid in detecting properly formed bonds during subsequent bonding of the package. Where plating is used, either electroplating or electroless plating may be utilized to form the metal layer on the material of the leadframe structures.

In various leadframe implementations, the use of half etching to form the substrate opening may be employed. This half etching may take place to allow for etching of the substrate opening at the same time as half etching of other portions of the leadframe (like the leads/tie bars, etc.) or a half etching step may be employed that specifically etches the substrate opening itself. The particular chemistry of the etch will depend upon the material of the leadframe being etched.

In places where the description above refers to particular implementations of substrate attach pads and implementing components, sub-components, methods and sub-methods, it should be readily apparent that a number of modifications may be made without departing from the spirit thereof and that these implementations, implementing components, sub-components, methods and sub-methods may be applied to other substrate attach pads.

What is claimed is:

1. A leadframe comprising:
a substrate attach portion comprising a first largest planar surface and a second largest planar surface on a side opposing the first largest planar surface; and
a substrate opening formed in a material of the first largest planar surface of the substrate attach portion;
wherein the substrate opening is configured to receive a perimeter of a substrate therein.

2. The leadframe of claim 1, wherein the substrate attach portion is one of a plurality of substrate attach portions where each of the plurality of substrate attach portions comprises a substrate opening.

3. The leadframe of claim 1, further comprising one or more leads fixedly coupled to the substrate attach portion.

4. The leadframe of claim 1, further comprising one or more leads fixedly coupled to the substrate attach portion through one or more tie bars.

5. The leadframe of claim 1, wherein the substrate attach portion forms an electrical connection with the substrate through the substrate opening.

6. The leadframe of claim 1, wherein a perimeter of the substrate opening is larger than a perimeter of the substrate.

7. The leadframe of claim 1, wherein the substrate comprises one or more semiconductor die thereon.

8. The leadframe of claim 1, wherein the substrate is a direct bonded copper substrate.

9. A semiconductor package comprising:
a leadframe comprising:
a substrate attach portion; and
a substrate recess formed into a material of the substrate attach portion;
wherein the substrate recess receive an entire perimeter of a substrate therein;
and
the substrate comprising at least one semiconductor die coupled thereto, the substrate coupled into the substrate recess.

10. The package of claim 9, wherein the substrate attach portion is one of a plurality of substrate attach portions where each of the plurality of substrate attach portions comprises a substrate recess.

11. The package of claim 9, further comprising one or more leads fixedly coupled to the substrate attach portion.

12. The package of claim 9, further comprising one or more leads fixedly coupled to the substrate attach portion through one or more tie bars.

13. The package of claim 9, wherein the substrate attach portion forms an electrical connection with the substrate through the substrate recess.

14. The package of claim 9, wherein a perimeter of the substrate recess is larger than a perimeter of the substrate.

15. The package of claim 9, wherein the substrate comprises two or more semiconductor die.

16. The package of claim 9, wherein the substrate is a direct bonded copper substrate.

17. A method of forming a substrate, the method comprising:
providing a substrate attach portion with a largest planar surface; and
one of stamping, punching, drilling, etching, or cutting a substrate recess into a material of the largest planar surface of the substrate attach portion;
wherein the substrate recess is sized to receive an entire perimeter of a second substrate therein.

18. The method of claim 17, further comprising dispensing a substrate attach material into the substrate recess.

19. The method of claim 18, further comprising placing a substrate into the substrate recess onto the substrate attach portion.

20. The method of claim 19, further comprising one of curing, sintering, or reflowing the substrate attach material to the substrate.
